(19) United States
(12) Patent Application Publication
(10) Pub. No.: US 2022/0334983 A1
(43) Pub. Date: Oct. 20, 2022

(54) Techniques For Sharing Memory Interface Circuits Between Integrated Circuit Dies

(71) Applicant: Intel Corporation, Santa Clara, CA (US)

(72) Inventors: Mahesh Kumashikar, Bangalore (IN); Md Altaf Hossain, Portland, OR (US); Ankireddy Nalamalpu, Portland, OR (US); Sreedhar Ravipalli, Cupertino, CA (US)

(73) Assignee: Intel Corporation, Santa Clara, CA (US)

(21) Appl. No.: 17/852,093

(22) Filed: Jun. 28, 2022

(51) Int. Cl. G06F 13/16

(52) U.S. Cl. CPC G06F 13/16; G06F 2213/16

(57) ABSTRACT

A circuit system includes a processing integrated circuit die comprising a first die-to-die interface circuit and a memory interface circuit. The circuit system also includes a second integrated circuit die comprising a second die-to-die interface circuit and a compute circuit that performs computations for the processing integrated circuit die. The first and the second die-to-die interface circuits are coupled together. The compute circuit is coupled to exchange information with the memory interface circuit through the first and the second die-to-die interface circuits.

### FIELD OF THE DISCLOSURE

The present disclosure relates to electronic circuit systems, and more particularly, to techniques for sharing memory interface circuits between integrated circuit dies.

### BACKGROUND

Configurable logic integrated circuits can be configured by users to implement desired custom logic functions. In a typical scenario, a logic designer uses computer-aided design tools to design a custom logic circuit. When the design process is complete, the computer-aided design tools generate configuration data. The configuration data is then loaded into configuration memory elements that configure configurable logic circuits in the integrated circuit to perform the functions of the custom logic circuit. Configurable logic integrated circuits can be used for co-processing in big-data or fast-data applications. For example, configurable logic integrated circuits may be used in application acceleration tasks in a datacenter and may be reprogrammed during datacenter operation to perform different tasks.

### BRIEF DESCRIPTION OF THE DRAWINGS

FIG. 1 is a diagram that illustrates an example of an infrastructure processing system (IPS) that includes a main processing integrated circuit (IC) die, an accelerator IC die that accelerates functions for the main processing IC die, and a compute IC die that performs processing operations.

FIG. 2 is a diagram that illustrates another example of an infrastructure processing system (IPS) that includes a main processing integrated circuit (IC) die and an accelerator and compute IC die.

FIG. 3 is a diagram that illustrates a top down view of an example of a network interface system (NIS) that includes a main processing integrated circuit (IC) die and an accelerator IC die that are positioned side-by-side in NIS.

FIG. 4 is a diagram that illustrates a top down view of another example of a network interface system (NIS) that includes the main processing integrated circuit (IC) die and the accelerator IC die.

FIG. 5 illustrates a side view of an exemplary configuration of the circuit system of FIG. 4.

FIG. 6 illustrates a side view of an exemplary configuration of a circuit system including IC dies that are coupled together through an interposer.

FIG. 7 illustrates a side view of an exemplary configuration of the IPS of FIG. 1.

FIG. 8 is a diagram that illustrates examples of a datacenter, a communications network, and a client system.

FIG. 9 is a diagram of an illustrative programmable (i.e., configurable) logic integrated circuit (IC) that may be programmed according to a user design to implement one of the main processing IC dies disclosed herein.

### DETAILED DESCRIPTION

A server computer in a datacenter can include one or more host processors and one or more coprocessors that function as acceleration devices. The host processor may be tasked to perform a pool of jobs/tasks. In order to improve the speed at which these tasks are performed, one or more of the coprocessor integrated circuit (IC) dies can be used to perform a subset of the pool of tasks. The host processor can send acceleration requests to one of the coprocessor IC dies. The coprocessor IC die functions as an accelerator circuit.

Hardware acceleration devices may be used for co-processing in big-data, fast-data, or high performance compute (HPC) applications in one or more server computers in a datacenter. By offloading acceleration functions (e.g., computationally intensive tasks) from a host processor to one or more coprocessors that function as acceleration devices, the host processor is freed up to perform other critical processing tasks. The use of hardware accelerators can therefore help deliver improved speed, latency, power efficiency, and flexibility for acceleration functions, such as cryptography, end-to-end cloud computing, networking, storage, artificial intelligence, autonomous driving, virtual reality, augmented reality, gaming, and other data-centric applications. An acceleration device may be a programmable logic integrated circuit (IC), such as a field programmable gate array (FPGA) that contains soft logic circuitry programmed to perform acceleration functions for a host processor, an application specific IC (ASIC) that contains hard logic circuitry designed to perform acceleration functions for a host processor, or an IC that combines soft and hard logic circuitry.

This disclosure discusses circuit systems that can be implemented in integrated circuit devices, including configurable (programmable) logic devices such as field programmable gate arrays (FPGAs). As discussed herein, an integrated circuit (IC) may include hard logic and/or soft logic. As used herein, “hard logic” generally refers to circuits in an integrated circuit device that are not programmable by an end user. The circuits in an integrated circuit device (e.g., in a configurable IC) that are programmable by the end user are referred to as “soft logic.”

Accelerator circuits can, for example, be used in server computers to perform networking functions for packets of data that are transmitted to the server computers through one or more networks. The accelerator circuits can use compute processing circuits to set up routing for new packets of data that are transmitted to the server computers through a network. The accelerator circuits may send control signals, such as interrupts, to the compute processing circuits to start the routing set up operations.

A compute processing circuit can be in the same integrated circuit die as the accelerator circuit that controls the compute processing circuit. Alternatively, the compute processing circuit and the accelerator circuit can be in separate integrated circuit (IC) dies. The compute processing circuit and the accelerator circuit can be in the same IC die as a programmable logic IC (e.g., an FPGA) or in separate IC dies. The IC dies in a circuit system, such as an IC package, can be coupled together through various types of interconnections.

According to some examples disclosed herein, an infrastructure processing system (IPS) includes a main processing integrated circuit (IC) die, an accelerator circuit that accelerates functions for the IPS, and a compute circuit that performs computations for the accelerator circuit or for the main processing IC die. The infrastructure processing system (IPS) can be, for example, a programmable network device that intelligently manages system-level infrastructure resources by securely accelerating functions in a datacenter. The IPS can accelerate infrastructure functions, including storage virtualization, network virtualization, and security with dedicated protocol accelerators. The IPS can free up processing cores by shifting storage and network virtualization functions that were previously performed in software on the processing cores to the IPS.

In the IPS, the accelerator and compute circuits can be in the same IC die or in separate IC dies. In some exemplary implementations, the accelerator circuit and the compute circuit are in separate IC dies that are each coupled to the main processing IC die through die-to-die input/output interface circuits. In other exemplary implementations, the accelerator circuit and the compute circuit are in the same IC die that is coupled to the main processing IC die through die-to-die input/output interface circuits. The main processing IC die includes one or more memory input/output interfaces for communicating with one or more external memory devices. The accelerator circuit and the compute circuit communicate with the external memory devices through the die-to-die input/output interface circuits, the main processing IC die, and the memory interfaces.

Throughout the specification, and in the claims, the term “connected” means a direct electrical connection between the circuits that are connected, without any intermediary devices. The term “coupled” means either a direct electrical connection between circuits or an indirect electrical connection through one or more passive or active intermediary devices. The term “circuit” may mean one or more passive and/or active electrical components that are arranged to cooperate with one another to provide a desired function.

One or more specific examples are described below. In an effort to provide a concise description of these examples, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

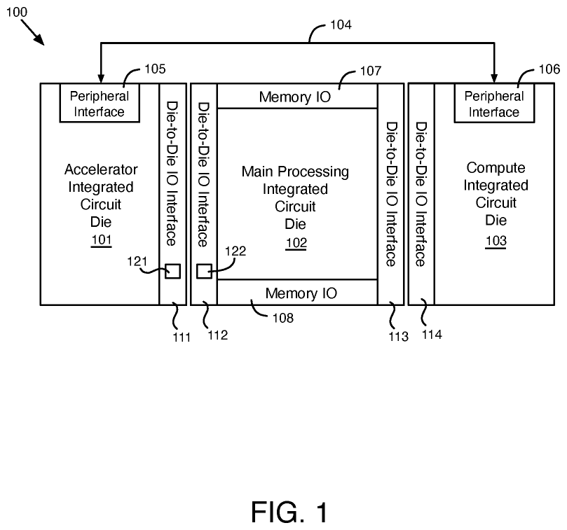

FIG. 1 is a diagram that illustrates an example of an infrastructure processing system (IPS) 100 that includes a main processing integrated circuit (IC) die 102, an accelerator IC die 101 that accelerates functions for the main processing IC die, and a compute IC die 103 that performs processing operations. The compute IC die 103 may be, for example, a processor integrated circuit (IC), such as a microprocessor IC, a central processing unit (CPU), or a graphics processing unit (GPU). The acceleration IC die 101 may be, for example, a programmable logic integrated circuit (IC), such as a field programmable gate array (FPGA) that contains soft logic circuitry programmed to perform acceleration functions, an application specific IC (ASIC) that contains hard logic circuitry designed to perform acceleration functions, or an IC that combines soft and hard logic circuitry. The main processing IC die 102 may be, for example, a programmable logic IC die, such as a FPGA, or a processor IC die, such as a microprocessor, CPU, or a graphics processing unit (GPU) IC die. IC dies 101-103 can, for example, be housed in the same integrated circuit package or coupled to a circuit board.

In the example of FIG. 1, network traffic that includes packets of data can be transmitted through a network to the main processing IC die 102. The main processing IC die 102 and the accelerator IC die 101 perform networking functions for the packets of data to generate processed packets of data. The main processing IC die 102 and the accelerator IC die 101 can, for example, perform networking functions that are defined according to one or more of the layers of the Open Systems Interconnection (OSI) model. The main processing IC die 102 and the accelerator IC die 101 can, for example, function as dedicated protocol accelerators that accelerate security functions, such as encrypting and decrypting the packets of data transmitted through the network. As other examples, the main processing IC die 102 and the accelerator IC die 101 can, for example, accelerate infrastructure functions, including storage virtualization and network virtualization.

The compute IC die 103 can perform processing operations, such as computations, for the accelerator IC die 101 or for the main processing IC die 102. The compute IC die 101 can, for example, set up routing tables for new connections for routing the new packets of data within the IPS 100 that are transmitted to main processing IC die 102 through a network. The main processing IC die 102 provides the new packets of data to the compute IC die 103. The compute IC die 103 provides the routing tables to the main processing IC die 102.

The accelerator IC die 101 includes die-to-die input/output (IO) interface circuit 111 on one side of the IC die. The main processing IC die 102 includes die-to-die input/output (IO) interface circuits 112 and 113 on opposite sides of the IC die. The compute IC die 103 includes die-to-die input/output (IO) interface circuit 114 on one side of the IC die. The accelerator IC die 101 is coupled to the main processing IC die 102 through die-to-die input/output interface circuit 111, die-to-die input/output interface circuit 112, and external interconnections in IPS 100. The compute IC die 103 is coupled to the main processing IC die 102 through die-to-die input/output interface circuit 114, die-to-die input/output interface circuit 113, and external interconnections in IPS 100. The external interconnections that couple together the die-to-die input/output interface circuits 111-112 and 113-114 can, for example, include conductive pads and bumps and conductors in a package substrate, interposer, or embedded interconnection bridge. The die-to-die input/output interface circuits 111-112 and 113-114 can, for example, include input driver circuits and output driver circuits, such as input/output driver circuits 121-122 in interface circuits 111-112, respectively, that are configured to transmit signals according to any interconnect protocol or standard. For example, die-to-die input/output interface circuits 111-112 and 113-114 can be configured to transmit signals according to a high bandwidth, high density interconnect protocol, such as Universal Chiplet Interconnect Express (UCIe)®.

The main processing IC die 102 also includes memory input/output (IO) interface circuits 107 and 108 adjacent to the top and bottom sides of the IC die 102. Main processing IC die 102 communicates with external memory devices using the memory TO interface circuits 107-108. In some implementations, the main IC die 102, the accelerator IC die 101, and the compute IC die 103 all use the memory IO interface circuits 107-108 to communicate with the external memory devices, as disclosed in further detail below. Sharing the memory IO interface circuits 107-108 between the IC dies 101-103 reduces the compute IC die area and reduces system cost and power consumption by using fewer external memory interfaces.

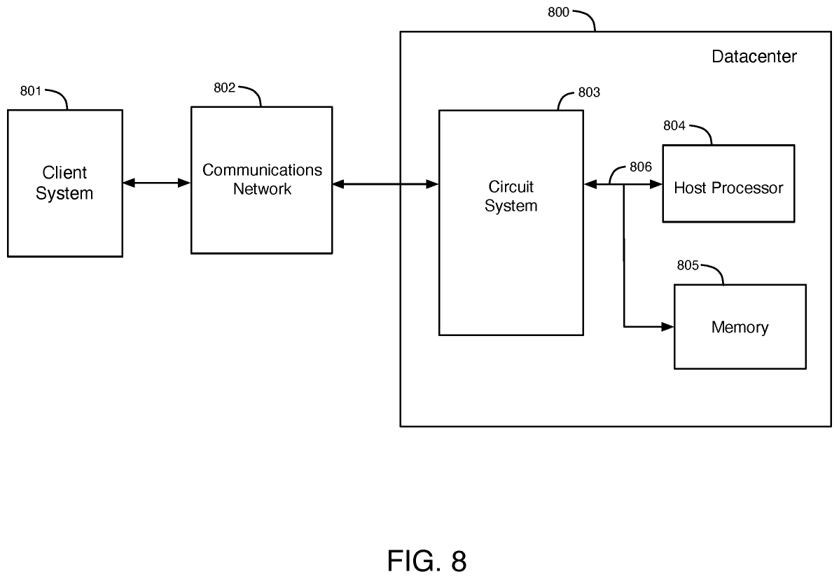

The memory TO interface circuits 107-108 can, for example, include input driver circuits and output driver circuits that are configured to process and transmit data, clock, and control signals according to any memory communications protocol or standard, such as Compute Express Link (CXL), Double Data Rate 4 Synchronous Dynamic Random-Access Memory (DDR4 SDRAM), Double Data Rate 5 Synchronous Dynamic Random-Access Memory (DDR5 SDRAM), or another version of a Double Data Rate (DDR) standard. An example of one or more of the external memory devices is disclosed herein with respect to FIG. 8.

The accelerator IC die 101 can communicate with the external memory devices using the memory TO interface circuits 107-108 in the main processing IC die 102. The accelerator IC die 101 can provide information (e.g., write data and/or control signals) to the main processing IC die 102 through the die-to-die TO interface circuits 111-112. The main processing IC die 102 can then forward the information received from the accelerator IC die 101 to the external memory devices through one or both of the memory TO interface circuits 107-108. In addition, the main processing IC die 102 can forward information (e.g., read data) received from the external memory devices through one or both of the memory IO interface circuits 107-108 to the accelerator IC die 101 through die-to-die IO interface circuits 111-112. As specific examples, the main processing die 102 can receive write requests, read requests, and write data from the accelerator IC die 101 through the die-to-die TO interface circuits 111-112. The main processing IC die 102 can then transmit the write requests, read requests, and write data to the external memory devices through one or both of the memory IO interface circuits 107-108. As another example, the main processing IC die 102 can receive read data from the external memory devices through the memory IO interface circuits 107-108. The main processing IC die 102 can then transmit the read data to the accelerator IC die 101 through die-to-die IO interface circuits 111-112.

The compute IC die 103 can also communicate with the external memory devices using the memory IO interface circuits 107-108 in the main processing IC die 102. The compute IC die 103 can provide information (e.g., write data and/or control signals) to the main processing IC die 102 through the die-to-die IO interface circuits 113-114. The main processing IC die 102 can then forward the information received from the compute IC die 103 to the external memory devices through one or both of the memory IO interface circuits 107-108. In addition, the main processing IC die 102 can forward information received from the external memory devices through one or both of the memory IO interface circuits 107-108 to the compute IC die 103 through die-to-die IO interface circuits 113-114. As specific examples, the main processing die 102 can receive write requests, read requests, and write data from the compute IC die 103 through the die-to-die IO interface circuits 113-114. The main processing IC die 102 can then transmit the write requests, read requests, and write data to the external memory devices through one or both of the memory IO interface circuits 107-108. As another example, the main processing IC die 102 can receive read data from the external memory devices through the memory IO interface circuits 107-108. The main processing IC die 102 can then transmit the read data to the compute IC die 103 through die-to-die IO interface circuits 113-114.

The accelerator IC die 101 also includes a peripheral interface circuit 105. The compute IC die 103 also includes a peripheral interface circuit 106. The peripheral interface circuits 105 and 106 can, for example, be configured to transmit signals according to the Peripheral Component Interconnect Express (PCIe) standard. The accelerator IC die 101 and the compute IC die 103 are configured to communicate directly with each other by exchanging signals (such as data, control, and clock signals) through bus 104 using the peripheral interface circuits 105-106.

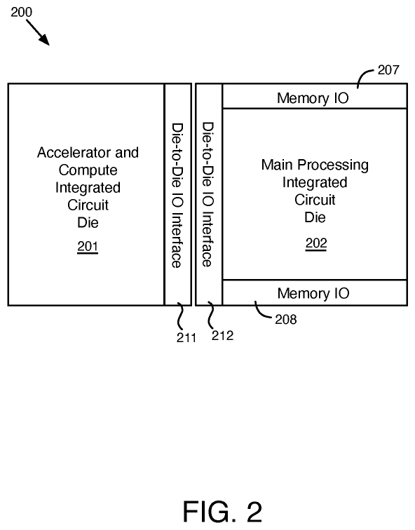

FIG. 2 is a diagram that illustrates another example of an infrastructure processing system (IPS) 200 that includes a main processing integrated circuit (IC) die 202 and an accelerator and compute IC die 201. The accelerator and compute IC die 201 includes an accelerator circuit that accelerates functions for the main processing IC die 202. The accelerator and compute IC die 201 also includes a compute circuit that performs computations for the accelerator circuit in IC die 201 or for the main processing IC die 202. The accelerator and compute IC die 201 may be, for example, a processor integrated circuit (IC), such as a microprocessor IC, a GPU, or a central processing unit (CPU), a programmable logic integrated circuit (IC), such as a field programmable gate array (FPGA) that contains soft logic circuitry programmed to perform acceleration and compute functions, an application specific IC (ASIC) that contains hard logic circuitry designed to perform acceleration and compute functions, or an IC that combines soft and hard logic circuitry. The main processing IC die 202 may be, for example, a programmable logic IC die, such as a FPGA, or a processor IC die, such as a microprocessor, CPU, or GPU IC die. IC dies 201-202 can, for example, be housed in the same integrated circuit package or circuit board.

In the example of FIG. 2, network traffic that includes packets of data can be transmitted through a network to the main processing IC die 202. The main processing IC die 202 and the accelerator circuit in IC die 201 perform networking functions for the packets of data to generate processed packets of data, for example, according to one or more of the layers of the OSI model. The main processing IC die 202 and the accelerator circuit in IC die 201 can, for example, function as dedicated protocol accelerators that accelerate security functions, such as encrypting and decrypting the packets of data transmitted through the network. As other examples, the main processing IC die 202 and the accelerator circuit in IC die 201 can, for example, accelerate infrastructure functions, including storage virtualization and network virtualization. The compute circuit in IC die 201 can perform processing operations, such as computations, for the accelerator circuit in IC die 201 or for the main processing IC die 202. The compute circuit can, for example, set up routing tables for new connections for routing the new packets of data within the IPS 200 that are transmitted to main processing IC die 202 through the network. The main processing IC die 202 provides the new packets of data to the compute circuit. The compute circuit provides the routing tables to the IC die 202.

The accelerator and compute IC die 201 includes die-to-die input/output (TO) interface circuit 211 on one side of the IC die. The main processing IC die 202 includes a die-to-die input/output (TO) interface circuit 212 on one side of the IC die. The accelerator and compute IC die 201 is coupled to the main processing IC die 202 through die-to-die input/output interface circuit 211, die-to-die input/output interface circuit 212, and external interconnections in IPS 200. The external interconnections that couple together die-to-die input/output interface circuits 211-212 can, for example, include conductive bumps and pads and conductors in a package substrate, interposer, or embedded interconnection bridge. The die-to-die input/output interface circuits 211-212 can, for example, include input driver circuits and output driver circuits configured to transmit signals according to any interconnect protocol or standard. For example, die-to-die input/output interface circuits 211-212 can be configured to transmit signals according to a high bandwidth, high density interconnect protocol, such as Universal Chiplet Interconnect Express (UCIe)®.

The main processing IC die 202 includes memory input/output (TO) interface circuits 207 and 208 adjacent to the top and bottom sides of the IC die. Main processing IC die 202 communicates with external memory devices (not shown) through the memory IO interface circuits 207-208. In some implementations, the main processing IC die 202 and the accelerator and compute IC die 201 all use the memory IO interface circuits 207-208 to communicate with the external memory devices, as disclosed in further detail below. Sharing the memory IO interface circuits 207-208 between the IC dies 201-202 reduces the compute IC die area and reduces system cost and power consumption by using fewer external memory interfaces.

The memory IO interface circuits 207-208 can, for example, include input driver circuits and output driver circuits that are configured to receive, process, and transmit signals according to any memory communications protocol or standard, such as Compute Express Link (CXL), Double Data Rate 4 Synchronous Dynamic Random-Access Memory (DDR4 SDRAM), Double Data Rate 5 Synchronous Dynamic Random-Access Memory (DDR5 SDRAM), or another version of Double Data Rate (DDR) standard. An example of one or more of the external memory devices is disclosed herein with respect to FIG. 8.

The accelerator and compute IC die 201 can communicate with the external memory devices using the memory IO interface circuits 207-208 in the main processing IC die 202. The accelerator and compute IC die 201 can provide information (e.g., write data and/or control signals) to the main processing IC die 202 through the die-to-die IO interface circuits 211-212. The main processing IC die 202 can then forward the information received from the accelerator and compute IC die 201 to the external memory devices through one or both of the memory IO interface circuits 207-208. In addition, the main processing IC die 202 can forward information received from the external memory devices through one or both of the memory IO interface circuits 207-208 to the accelerator and compute IC die 201 through die-to-die IO interface circuits 211-212. As specific examples, IC die 201 can transmit write requests, read requests, and write data to the main processing IC die 202 through the die-to-die IO interface circuits 211-212. The main processing IC die 202 can then transmit the write requests, read requests, and write data to the external memory devices through one or both of the memory IO interface circuits 207-208. As another example, the main processing IC die 202 can receive read data accessed from the external memory devices through the memory IO interface circuits 207-208, and then transmit the read data to IC die 201 through die-to-die IO interface circuits 211-212.

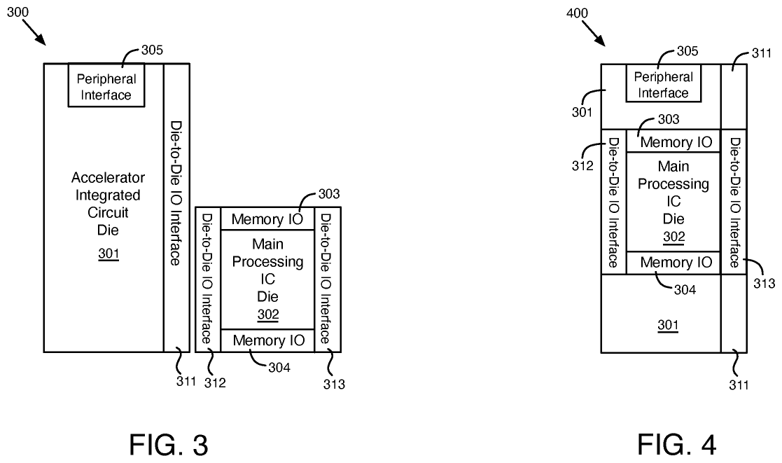

FIG. 3 is a diagram that illustrates a top down view of an example of a network interface system (NIS) 300 that includes a main processing integrated circuit (IC) die 302 and an accelerator IC die 301 that are positioned side-by-side in NIS 300. The accelerator IC die 301 includes an accelerator circuit that accelerates functions for the main processing IC die 302. The main processing IC die 302 is smaller than the accelerator IC die 301. The accelerator IC die 301 may be, for example, a processor integrated circuit (IC), such as a microprocessor IC, GPU, or a central processing unit (CPU), a programmable logic integrated circuit (IC), such as a field programmable gate array (FPGA) that contains soft logic circuitry programmed to perform acceleration functions, an application specific IC (ASIC) that contains hard logic circuitry designed to perform acceleration functions, or an IC that combines soft and hard logic circuitry. The main processing IC die 302 may be, for example, a programmable logic IC die, such as a FPGA, or a processor IC die, such as a microprocessor, CPU, or a graphics processing unit (GPU) IC die. IC dies 301-302 can, for example, be mounted side-by-side in the same integrated circuit package. In the example of FIG. 3, network traffic that includes packets of data can be transmitted through a network to the main processing IC die 302. The main processing IC die 302 and the accelerator circuit in IC die 301 perform networking functions for the packets of data to generate processed packets of data. The NIS 300 can, for example, be in a foundational network interface card.

The accelerator IC die 301 includes die-to-die input/output (IO) interface circuit 311 on one side of the IC die. The main processing IC die 302 includes die-to-die input/output (IO) interface circuits 312-313 on opposite sides of the IC die. The accelerator IC die 301 is coupled to the main processing IC die 302 through die-to-die input/output interface circuit 311, die-to-die input/output interface circuit 312 and/or 313, and external interconnections in the network interface system 300. The external interconnections that couple together die-to-die input/output interface circuits 311-313 can, for example, include conductive bumps and pads and conductors in a package substrate, interposer, or embedded interconnection bridge. The die-to-die input/output interface circuits 311-313 can, for example, include input driver circuits and output driver circuits configured to transmit signals according to any interconnect protocol or standard. For example, die-to-die input/output interface circuits 311-313 can be configured to transmit signals according to a high bandwidth, high density interconnect protocol, such as UCIe®.

The main processing IC die 302 includes memory input/output (IO) interface circuits 303 and 304 adjacent to the top and bottom sides of the IC die. Main processing IC die 302 communicates with external memory devices (not shown) through the memory 10 interface circuits 303-304. As with the examples of FIGS. 1-2, the main processing IC die 302 and the accelerator IC die 301 can both use the memory 10 interface circuits 303-304 to communicate with the external memory devices. The accelerator IC die 301 can exchange data and control signals with the main processing IC die 302 through the die-to-die 10 interface circuits 311-313, and the main processing IC die 302 can exchange the data and control signals with the external memory devices through one or both of the memory IO interface circuits 303-304.

Sharing the memory IO interface circuits 303-304 between the IC dies 301-302 reduces system cost and power consumption by using fewer external memory interfaces. The memory IO interface circuits 303-304 can, for example, include input driver circuits and output driver circuits that are configured to process and transmit signals according to any memory communications protocol or standard, such as CXL, any version of DDR, etc. Accelerator IC die 301 also includes a peripheral interface circuit 305 that can exchange data with another external device using a peripheral device protocol, such as PCIe.

FIG. 4 is a diagram that illustrates a top down view of another configuration of a network interface system (NIS) 400 that includes the main processing integrated circuit (IC) die 302 and the accelerator IC die 301. In the example of FIG. 4, the main processing IC die 302 and the accelerator IC die 301 are vertically stacked, such that IC die 302 is mounted on top of IC die 301. The main processing IC die 302 is coupled to the accelerator IC die 301 through die-to-die 10 interface circuits 313 and 311 and conductive bumps and pads. IC dies 301-302 can, for example, have through silicon vias (TSVs). As with the example of FIG. 3, the accelerator IC die 301 can communicate with external memory devices through the die-to-die interface circuits 311 and 313 and through the memory IO interface circuits 303-304.

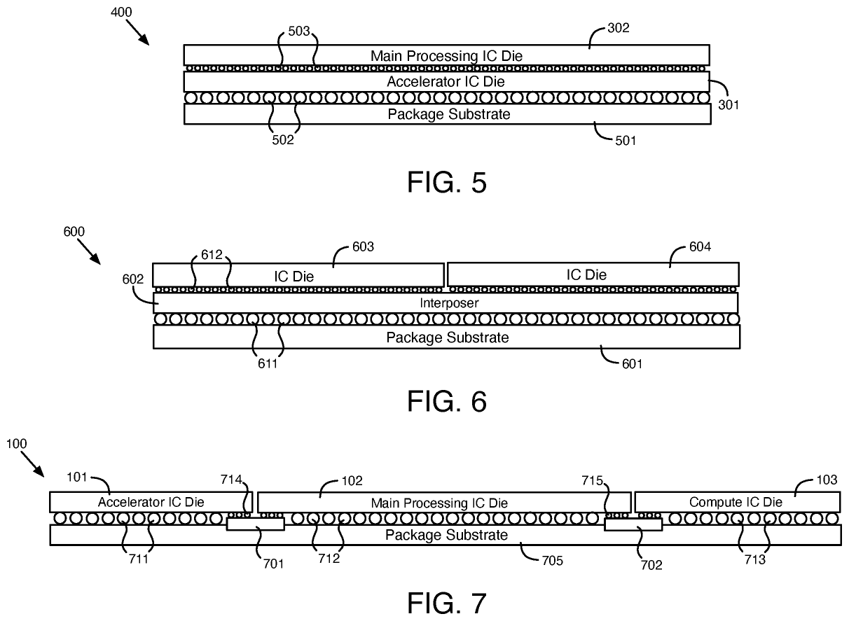

FIG. 5 illustrates a side view of an exemplary configuration of the system 400 of FIG. 4. In the example of FIG. 5, the system 400 is an integrated circuit (IC) package that includes IC dies 301-302, package substrate 501, and conductive bumps 502-503. As shown in FIG. 5, the main processing IC die 302 is stacked vertically on top of accelerator IC die 301 within the IC package to provide a three dimensional IC stack. The die-to-die 10 interface circuits 311 and 313 are coupled together through the conductive micro-bumps 503. Accelerator IC die 301 is coupled to the package substrate 501 of the IC package through conductive bumps 502.

FIG. 6 illustrates a side view of an exemplary configuration of a circuit system 600 including IC dies that are coupled together through an interposer. The circuit system 600 is an exemplary configuration for the circuit system of FIG. 2 and/or the circuit system of FIG. 3. The circuit system 600 includes a package substrate 601, an interposer 602, IC dies 603-604, conductive bumps 611, and conductive micro-bumps 612. The interposer 602 is coupled to IC dies 603-604 through the conductive micro-bumps 612. In the example of FIG. 2, IC dies 603-604 are IC dies 201-202, and the die-to-die 10 interface circuits 211 and 212 are coupled together through the micro-bumps 612 and through conductors in the interposer 602. In the example of FIG. 3, IC dies 603-604 are IC dies 301-302, and the die-to-die 10 interface circuits 311-313 are coupled together through the micro-bumps 612 and through conductors in the interposer 602.

FIG. 7 illustrates a side view of an exemplary configuration of the IPS 100 of FIG. 1. In the example of FIG. 7, IPS 100 is an integrated circuit (IC) package that includes IC dies 101-103, package substrate 705, conductive bumps 711-713, interconnection bridges 701-702, and conductive micro-bumps 714-715. The accelerator IC die 101, the main processing IC die 102, and the compute IC die 103 are coupled to the package substrate 705 through conductive bumps 711, 712, and 713, respectively. Accelerator IC die 101 and main processing IC die 102 are coupled to interconnection bridge 701 through micro-bumps 714. The die-to-die 10 interface circuits 111 and 112 are coupled together through the micro-bumps 714 and through conductors in interconnection bridge 701. Main processing IC die 102 and compute IC die 103 are coupled to interconnection bridge 702 through micro-bumps 715. The die-to-die 10 interface circuits 113 and 114 are coupled together through the micro-bumps 715 and through conductors in interconnection bridge 702.

FIG. 8 is a diagram that illustrates examples of a datacenter 800, a communications network 802, and a client system 801. Datacenter 800 includes a host processor 804, one or more external memory devices 805, and a circuit system 803. Circuit system 803 can be, for example, any one of IPS 100 of FIG. 1, IPS 200 of FIG. 2, the system 300 of FIG. 3, or the system 400 of FIG. 4. The external memory devices 805 can be any of the external memory devices discussed above with respect to FIGS. 1-4. The IC dies in the circuit system 803 can communicate with the external memory devices 805 through interconnects 806 using the memory 10 interfaces in the main processing IC die, as discussed above.

The client system 801 transmits packets of data to the circuit system 803 through the communications network 802. The circuit system 803 processes the packets of data as disclosed herein to generate processed packets of data. The processed packets of data are transmitted to host processor 804 and/or to memory devices 805 through interconnects 806. Host processor 804 can also generate packets of data that are transmitted to circuit system 803. Circuit system 803 can perform networking functions on the packets of data to generate processed packets of data that are transmitted to the client system 801 through communications network 802.

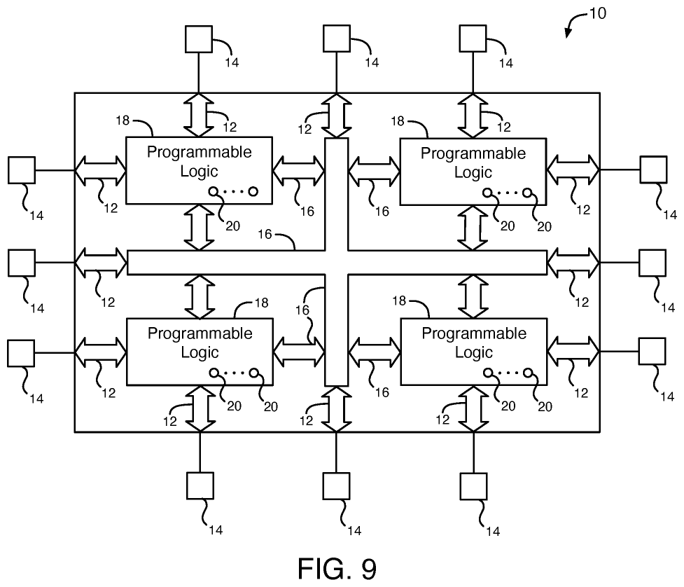

FIG. 9 is a diagram of an illustrative programmable (i.e., configurable) logic integrated circuit (IC) 10 that may be programmed according to a user design to implement one of the IC dies disclosed herein. As shown in FIG. 9, programmable logic integrated circuit 10 has input-output circuitry 12 for driving signals off of IC 10 and for receiving signals from other devices via input-output pads 14. Interconnection resources 16 such as global, regional, and local vertical and horizontal conductive lines and buses can be used to route signals on IC 10. Interconnection resources 16 include fixed interconnects (conductive lines) and programmable interconnects (i.e., programmable connections between respective fixed interconnects). Programmable logic circuitry 18 may include combinational and sequential logic circuitry. Programmable logic circuitry 18 can be configured to perform custom logic functions.

Programmable logic IC 10 contains memory elements 20 that can be loaded with configuration data using pads 14 and input-output circuitry 12. Once loaded, the memory elements 20 may each provide a corresponding static control output signal that controls the state of an associated logic component in programmable logic circuitry 18. Typically, the memory element output signals are used to control the gates of field-effect transistors. In the context of programmable integrated circuits, the memory elements 20 store configuration data and are sometimes referred to as configuration random-access memory (CRAM) cells. The configuration data programs the programmable logic 18 to perform the custom logic functions according to the user design.

In general, software and data for performing any of the functions disclosed herein may be stored in non-transitory computer readable storage media. Non-transitory computer readable storage media is tangible computer readable storage media that stores data for a significant period of time, as opposed to media that only transmits propagating electrical signals (e.g., wires). The software code may sometimes be referred to as software, data, program instructions, instructions, or code. The non-transitory computer readable storage media may, for example, include computer memory chips, non-volatile memory such as non-volatile random-access memory (NVRAM), one or more hard drives (e.g., magnetic drives or solid state drives), one or more removable flash drives or other removable media, compact discs (CDs), digital versatile discs (DVDs), Blu-ray discs (BDs), other optical media, and floppy diskettes, tapes, or any other suitable memory or storage device(s).

Additional examples are now described. Example 1 is a circuit system comprising: a processing integrated circuit die comprising a first die-to-die interface circuit and a first memory interface circuit; and a second integrated circuit die comprising a second die-to-die interface circuit and a compute circuit that performs computations for the processing integrated circuit die, wherein the first and the second die-to-die interface circuits are coupled together, and wherein the compute circuit is coupled to exchange information with the first memory interface circuit through the first and the second die-to-die interface circuits.

In Example 2, the circuit system of Example 1 can optionally include, wherein the second integrated circuit die further comprises an accelerator circuit that accelerates functions for the processing integrated circuit die, and wherein the accelerator circuit is coupled to exchange information with the first memory interface circuit through the first and the second die-to-die interface circuits.

In Example 3, the circuit system of Example 1 further comprises: an accelerator integrated circuit die comprising a third die-to-die interface circuit, wherein the processing integrated circuit die further comprises a fourth die-to-die interface circuit, wherein the third and the fourth die-to-die interface circuits are coupled together, and wherein the accelerator integrated circuit die is coupled to exchange information with the first memory interface circuit through the third and the fourth die-to-die interface circuits.

In Example 4, the circuit system of any one of Examples 1-3 can optionally include, wherein the compute circuit is configured to set up routing tables for connections for routing packets of data within the circuit system.

In Example 5, the circuit system of any one of Examples 1˜4 can optionally include, wherein the processing integrated circuit die further comprises a second memory interface circuit, and wherein the compute circuit is coupled to exchange information with the second memory interface circuit through the first and the second die-to-die interface circuits.

In Example 6, the circuit system of any one of Examples 1-5 can optionally include, wherein the first memory interface circuit is configured to exchange signals with a memory device external to the processing integrated circuit die.

In Example 7, the circuit system of any one of Examples 1-6 can optionally include, wherein the processing integrated circuit die is a programmable logic integrated circuit.

In Example 8, the circuit system of any one of Examples 1-7 can optionally include, wherein the processing integrated circuit die is configured to accelerate storage virtualization functions and network virtualization functions.

In Example 9, the circuit system of any one of Examples 1-8 can optionally include, wherein the first and the second die-to-die interface circuits are coupled together through interconnects in one of an interposer, a package substrate, or an interconnection bridge in the circuit system.

Example 10 is a method for sharing a first memory interface circuit in a processing integrated circuit die, comprising: receiving first data from a first external memory device using the first memory interface circuit; providing the first data from the first memory interface circuit to a compute circuit in a second integrated circuit die through a first die-to-die interface circuit in the processing integrated circuit die and through a second die-to-die interface circuit in the second integrated circuit die; and performing computations with the compute circuit using the first data received from the processing integrated circuit die.

In Example 11, the method of Example 10 further comprises: receiving second data from a second external memory device using the first memory interface circuit; providing the second data from the first memory interface circuit to an accelerator circuit in the second integrated circuit die through the first and the second die-to-die interface circuits; and accelerating operations for the processing integrated circuit die with the accelerator circuit using the second data.

In Example 12, the method of Example 10 further comprises: receiving second data from the first external memory device using the first memory interface circuit; providing the second data from the first memory interface circuit to an accelerator integrated circuit die through a third die-to-die interface circuit in the processing integrated circuit die and through a fourth die-to-die interface circuit in the accelerator integrated circuit die; and accelerating operations for the processing integrated circuit die with the accelerator integrated circuit die using the second data.

In Example 13, the method of any one of Examples 10-12 further comprises: receiving additional data from a memory device external to the processing integrated circuit die using a second memory interface circuit in the processing integrated circuit die; providing the additional data from the second memory interface circuit to the compute circuit through the first and the second die-to-die interface circuits; and performing additional computations with the compute circuit using the additional data received from the processing integrated circuit die.

In Example 14, the method of any one of Examples 10-13 can optionally include, wherein performing the computations with the compute circuit using the first data further comprises: setting up routing tables for connections for routing packets of data within a circuit system using the compute circuit.

In Example 15, the method of Example 10 further comprises: receiving second data from a second external memory device using a second memory interface circuit in the processing integrated circuit die; providing the second data from the second memory interface circuit to an accelerator integrated circuit die through a third die-to-die interface circuit in the processing integrated circuit die and through a fourth die-to-die interface circuit in the accelerator integrated circuit die; and accelerating operations for the processing integrated circuit die with the accelerator integrated circuit die using the second data.

Example 16 is a circuit system comprising: a processing integrated circuit die comprising a first die-to-die interface circuit, a first memory interface circuit, and a second memory interface circuit, wherein the first and the second memory interface circuits are adjacent to opposite sides of the processing integrated circuit die; and an accelerator integrated circuit die that accelerates functions for the processing integrated circuit die, wherein the accelerator integrated circuit die comprises a second die-to-die interface circuit that is coupled to the first die-to-die interface circuit, and wherein the accelerator integrated circuit die is coupled to exchange information with the first and the second memory interface circuits through the first and the second die-to-die interface circuits.

In Example 17, the circuit system of Example 16 can optionally include, wherein the accelerator integrated circuit die and the processing integrated circuit die are mounted side-by-side in the circuit system.

In Example 18, the circuit system of Example 16 can optionally include, wherein the accelerator integrated circuit die and the processing integrated circuit die are vertically stacked in the circuit system.

In Example 19, the circuit system of any one of Examples 16-18 can optionally include, wherein the processing integrated circuit die is configured to perform storage virtualization functions or network virtualization functions.

In Example 20, the circuit system of any one of Examples 16-19 can optionally include, wherein each of the first and the second die-to-die interface circuits comprises input driver circuits and output driver circuits configured to transmit signals according to an interconnect protocol.

The foregoing description of the examples has been presented for the purpose of illustration. The foregoing description is not intended to be exhaustive or to be limiting to the examples disclosed herein. In some instances, features of the examples can be employed without a corresponding use of other features as set forth. Many modifications, substitutions, and variations are possible in light of the above teachings.

What is claimed is:

1. A circuit system comprising:
a processing integrated circuit die comprising a first die-to-die interface circuit and a first memory interface circuit; and
a second integrated circuit die comprising a second die-to-die interface circuit and a compute circuit that performs computations for the processing integrated circuit die, wherein the first and the second die-to-die interface circuits are coupled together, and wherein the compute circuit is coupled to exchange information with the first memory interface circuit through the first and the second die-to-die interface circuits.

2. The circuit system of claim 1, wherein the second integrated circuit die further comprises an accelerator circuit that accelerates functions for the processing integrated circuit die, and wherein the accelerator circuit is coupled to exchange information with the first memory interface circuit through the first and the second die-to-die interface circuits.

3. The circuit system of claim 1 further comprising:
an accelerator integrated circuit die comprising a third die-to-die interface circuit, wherein the processing integrated circuit die further comprises a fourth die-to-die interface circuit, wherein the third and the fourth die-to-die interface circuits are coupled together, and wherein the accelerator integrated circuit die is coupled to exchange information with the first memory interface circuit through the third and the fourth die-to-die interface circuits.

4. The circuit system of claim 1, wherein the compute circuit is configured to set up routing tables for connections for routing packets of data within the circuit system.

5. The circuit system of claim 1, wherein the processing integrated circuit die further comprises a second memory interface circuit, and wherein the compute circuit is coupled to exchange information with the second memory interface circuit through the first and the second die-to-die interface circuits.

6. The circuit system of claim 1, wherein the first memory interface circuit is configured to exchange signals with a memory device external to the processing integrated circuit die.

7. The circuit system of claim 1, wherein the processing integrated circuit die is a programmable logic integrated circuit.

8. The circuit system of claim 1, wherein the processing integrated circuit die is configured to accelerate storage virtualization functions and network virtualization functions.

9. The circuit system of claim 1, wherein the first and the second die-to-die interface circuits are coupled together through interconnects in one of an interposer, a package substrate, or an interconnection bridge in the circuit system.

10. A method for sharing a first memory interface circuit in a processing integrated circuit die, comprising:
receiving first data from a first external memory device using the first memory interface circuit;
providing the first data from the first memory interface circuit to a compute circuit in a second integrated circuit die through a first die-to-die interface circuit in the processing integrated circuit die and through a second die-to-die interface circuit in the second integrated circuit die; and
performing computations with the compute circuit using the first data received from the processing integrated circuit die.

11. The method of claim 10 further comprising:
receiving second data from a second external memory device using the first memory interface circuit;
providing the second data from the first memory interface circuit to an accelerator circuit in the second integrated circuit die through the first and the second die-to-die interface circuits; and
accelerating operations for the processing integrated circuit die with the accelerator circuit using the second data.

12. The method of claim 10 further comprising:
receiving second data from the first external memory device using the first memory interface circuit;
providing the second data from the first memory interface circuit to an accelerator integrated circuit die through a third die-to-die interface circuit in the processing integrated circuit die and through a fourth die-to-die interface circuit in the accelerator integrated circuit die; and
accelerating operations for the processing integrated circuit die with the accelerator integrated circuit die using the second data.

13. The method of claim 10 further comprising:
receiving additional data from a memory device external to the processing integrated circuit die using a second memory interface circuit in the processing integrated circuit die;
providing the additional data from the second memory interface circuit to the compute circuit through the first and the second die-to-die interface circuits; and
performing additional computations with the compute circuit using the additional data received from the processing integrated circuit die.

14. The method of claim 10, wherein performing the computations with the compute circuit using the first data further comprises:
setting up routing tables for connections for routing packets of data within a circuit system using the compute circuit.

15. The method of claim 10 further comprising:
receiving second data from a second external memory device using a second memory interface circuit in the processing integrated circuit die;
providing the second data from the second memory interface circuit to an accelerator integrated circuit die through a third die-to-die interface circuit in the processing integrated circuit die and through a fourth die-to-die interface circuit in the accelerator integrated circuit die; and
accelerating operations for the processing integrated circuit die with the accelerator integrated circuit die using the second data.

16. A circuit system comprising:
a processing integrated circuit die comprising a first die-to-die interface circuit, a first memory interface circuit, and a second memory interface circuit, wherein the first and the second memory interface circuits are adjacent to opposite sides of the processing integrated circuit die; and
an accelerator integrated circuit die that accelerates functions for the processing integrated circuit die, wherein the accelerator integrated circuit die comprises a second die-to-die interface circuit that is coupled to the first die-to-die interface circuit, and wherein the accelerator integrated circuit die is coupled to exchange information with the first and the second memory interface circuits through the first and the second die-to-die interface circuits.

17. The circuit system of claim 16, wherein the accelerator integrated circuit die and the processing integrated circuit die are mounted side-by-side in the circuit system.

18. The circuit system of claim 16, wherein the accelerator integrated circuit die and the processing integrated circuit die are vertically stacked in the circuit system.

19. The circuit system of claim 16, wherein the processing integrated circuit die is configured to perform storage virtualization functions or network virtualization functions.

20. The circuit system of claim 16, wherein each of the first and the second die-to-die interface circuits comprises input driver circuits and output driver circuits configured to transmit signals according to an interconnect protocol.
